(19) United States
(12) Patent Application Publication
(10) Pub. No.: US 2022/0145747 A1
(43) Pub. Date: May 12, 2022

(54) DRILLING SYSTEMS AND METHODS

(71) Applicant: MHWIRTH AS, KRISTIANSAND (NO)

(72) Inventor: SIGVED BERDAL, KRISTIANSAND (NO)

(73) Assignee: MHWIRTH AS, KRISTIANSAND (NO)

(21) Appl. No.: 17/601,924

(22) PCT Filed: Apr. 2, 2020
(86) PCT No.: PCT/NO2020/050092

§ 371 Date: Oct. 7, 2021

(30) Foreign Application Priority Data
Apr. 10, 2019 (NO) 20190490

(51) Int. Cl. E21B 44/00; E21B 19/16; E21B 21/08; E21B 19/14; E21B 47/09; E21B 41/00

(52) U.S. Cl. CPC E21B 44/00; E21B 19/165; E21B 41/0007; E21B 19/14; E21B 47/09; E21B 21/08

(57) ABSTRACT

A drilling plant management system includes a database having information of equipment items on a drilling rig and in a well, a controller having a processor, and a tracker module. The information includes an identification and a location of each of the equipment items on the drilling rig or in the well. The controller receives update messages with the identification of an equipment item and information related to the equipment item, and updates the database with the information in the update message. Via the processor, the controller tracks a location of each of the equipment items and, once handled by a handling equipment, transmits an update message to the database with the identification of the equipment item and the location of the equipment item.

### CROSS REFERENCE TO PRIOR APPLICATIONS

This application is a U.S. National Phase application under 35 U.S.C. § 371 of International Application No. PCT/NO2020/050092, filed on Apr. 2, 2020 and which claims benefit to Norwegian Patent Application No. 20190490, filed on Apr. 10, 2019. The International Application was published in English on Oct. 15, 2020 as WO 2020/209725 A1 under PCT Article 21(2).

### FIELD

The present invention relates to drilling systems and methods, including but not limited to systems and methods for managing and operating offshore drilling rigs and associated equipment.

### BACKGROUND

In drilling operations, such as offshore petroleum exploration, various operations are usually carried out by highly specialized vessels or rigs. The operation of such vessels or rigs can be very costly and make up a substantial part of the cost of a well. Due to the high cost, operational efficiency and reliability during these processes is of great importance.

Drilling operations are complex logistic operations that need to keep track of the inventory and positions of all the drill pipes, casings, and drill strings components. For offshore drilling operations, it is also important to know the future needs of drill pipes, casings, and drill string components, as they must be transported from land by supply ships over long distances. Sea transport is also often complicated and prone to delays by severe offshore sea and weather conditions. This is further complicated by limited available storage space on the rigs.

The position of tools, such as the drill bit, in sub-surface environments is often determined by keeping track of the drill string length which is determined by keeping track of the pipes in a tally book, typically a computer spreadsheet. To confirm at any stage what depth the drill bit is operating at, the driller consults the pipe tally records, and measures the length of the current stand of drill pipe below the rig floor. However, drill pipes already vary in length directly from production, and in use, damaged pipes may be reworked and machined, for example, by a re-cut, thereby shorting the pipes. Drill pipes may also be subjected to high mechanical loads during drilling and thereby change length. The manual update of spreadsheets during the alternating running in and running out the drill pipes during drilling operations is prone to error, thereby resulting in a limited accuracy of the exact position of the equipment.

Publications which may be useful to understand the field of technology include US 2014/0365129 A1, which describes an oilfield equipment identification method and apparatus; U.S. Pat. No. 6,371,204 B 1, which describes an underground well kick detector; and U.S. Pat. No. 9,418,266 B1, which describes tracking oilfield assets with a universal identification protocol.

There is consequently a continuous need for improved systems and techniques for operating drilling plants efficiently.

### SUMMARY

An aspect of the present invention is to provide drilling plant systems and methods which can realize advantages over known solutions and techniques in the above-mentioned or other areas, or at least provide alternatives thereto.

In an embodiment the present invention provides a drilling plant management system which includes a database comprising information of equipment items on a drilling rig and in a well, a controller comprising a processor, and a tracker module. The information comprises an identification and a location of each of the equipment items on the drilling rig or in the well. The controller is configured to receive update messages comprising the identification of an equipment item and information related to the equipment item, and to update the database with the information in the update message. The controller is configured, via the processor, to track a location of each of the equipment items and, once handled by a handling equipment, to transmit an update message to the database comprising the identification of the equipment item and the location of the equipment item.

### BRIEF DESCRIPTION OF THE DRAWINGS

The present invention is described in greater detail below on the basis of embodiments and of the drawings in which:

FIG. 1 is a schematic illustration of an offshore drilling rig;

FIG. 2 is a schematic illustration of a first embodiment of the present invention;

FIG. 3 is a schematic illustration of a second embodiment of the present invention;

FIG. 4 is a schematic illustration of a third embodiment of the present invention;

FIG. 5 is a schematic illustration of a fourth embodiment of the present invention; and

FIG. 6 is a schematic illustration of a sixth embodiment of the present invention.

### DETAILED DESCRIPTION

In an embodiment, the present invention provides a drilling plant management system comprising a database comprising information of a plurality of equipment items on a drilling rig and in a well, the information comprising an identification and a location of each of the plurality of equipment items on the drilling rig or in the well, a controller having a processor adapted to receive update messages comprising the identification of an equipment item and information related to the equipment item, and update the database with the information in the update message; and a tracker module having a processor adapted to, for each of the plurality of equipment items, track the location of the equipment item and, once handled by a handling equipment, transmit an update message to the database comprising the identification of the equipment items and the location of the equipment items.

In an embodiment, the present invention provides a method of estimating a fluid volume in a well using a drilling plant management system, the method comprising: providing a plurality of tubulars to a drilling rig; logging physical dimensions of each tubular in the database, the physical dimensions including a volume of material for the tubular; logging with the tracking module tubulars that are positioned the well; determining material volume of the tubulars positioned in the well; and calculating the fluid volume based on well dimensions and the combined material volume of the tubulars in the well.

In an embodiment, the present invention provides a method for determining a position of a part of a tool string in relation to a well using a drilling plant management system, the method comprising: determining, based on the location of each equipment item in the database, all equipment items located in the well; determining, based on the information of each equipment item in the database, the length of each equipment item located in the well; determining the total length a well string by summing up the length of each equipment item located in the well; and determining the position of the part of the tool string in relation to the well based on the determined total length of the well string.

In an embodiment, the present invention provides a method of operating a drilling rig, the method comprising: operating the drilling rig according to a well plan and a planned sequence of building a drill string from a plurality of equipment items and bringing the drill string into a well, each equipment item prior to being arranged in the drill string being positioned in a defined position on the rig stored in a database; identifying a change in the well plan or the planned sequence and a need to prematurely retrieve the drill string from the well; operating a planner module to, in this order, (i) plan a subsequent construction sequence of the drill string from the plurality of equipment items in view of physical properties of each equipment item received from the database, and (ii) allocate a defined position on the rig to each equipment element to be retrieved from the well; and operating the drilling rig to: (i) retrieve the drill string from the well, break up the drill string, and place each equipment item broken out of the drill string in the allocated position for that equipment item, and (ii) retrieve a plurality of equipment items from their storage positions, build a drill string according to the planned sequence, and introduce the drill string into the well.

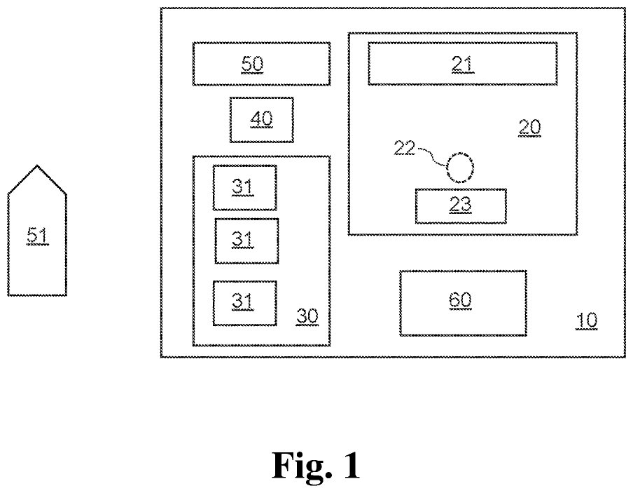

Referring now to FIG. 1, there is illustrated an offshore drilling rig 10, comprising a drill floor 20, a pipe deck 30, a pipe deck pipe handler 40, and a tubular feeding machine 50. The pipe deck comprises a plurality of bays 31 for storing drill pipes, risers, casings, and drill string components, which is referred to as tubulars below unless otherwise specified. The pipe deck pipe handler 40, for example, a crane, transports tubulars from the pipe deck 30 to the tubular feeding machine 50. The tubular feeding machine 50 in turn, transports the tubulars to and from the drill floor 20. On the drill floor 20, the tubulars are handled by further machines, for example, a vertical pipe handling system (which is not shown in the drawing). For drill pipe, multiple sections of drill string, typically three, are mounted together into a stand and stored in fingerboards 21. The vertical pipe handling system further moves the stands to and from a well center 22 where the drill string and other tubulars are run in and out of a well via a hoisting and drilling system 23. The hoisting and drilling system 23 may comprise a derrick with a top drive, as is known in the art. FIG. 1 further illustrates a supply ship 51 providing tubulars to the drilling rig. The tubulars on the supply ship 51 are lifted onto the bays 31 of the pipe deck 30.

While described herein is an offshore drilling rig, the offshore drilling rig 10 may alternatively be a land based drilling rig, with the supply being provided by a land vehicle, such as a truck. Embodiments of the present invention may be suitable for use with any type of drilling rig, such as land-based rigs, fixed offshore rigs, jack-up rigs, or floaters.

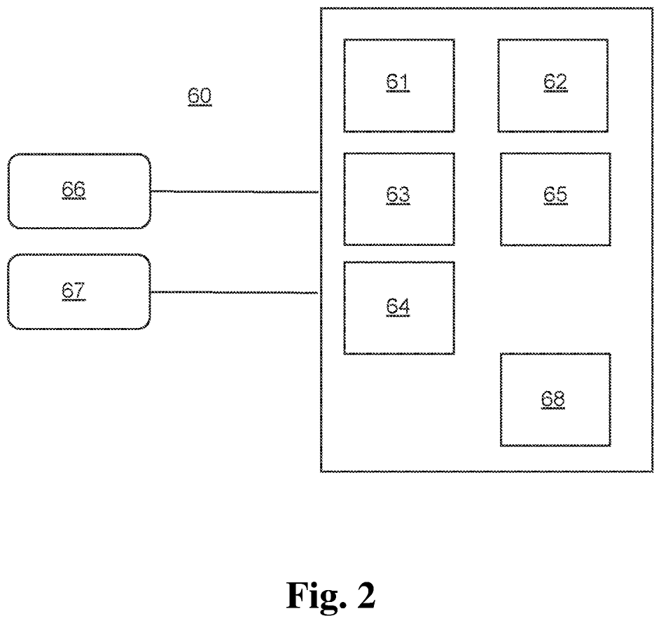

The offshore drilling rig 10 comprises a drilling plant management system 60 for managing equipment on the offshore drilling rig 10 and in the well, in particular in the context of working processes. As illustrated in FIG. 2, the system 60 comprises a database 61 and a tracker module 62. The system 60 may also comprise one or more of a planner module 63, a graphical interface module 64, and a condition tracker module 65. The system 60 further comprises a controller having a processor 68 which is adapted to execute functions required by the tracker module 62, the planner module 63, the graphical interface module 64, and the condition tracker module 65. The controller is adapted to receive update messages comprising the identification of an equipment and information related to the equipment, and to update the database 61 with the information in the update message. The system 60 may further comprise a plurality of scanners 66 and measurement devices 67 that provides input to the system 60 as will be described in further detail below.

The database 61 comprises an inventory of a plurality of equipment on the offshore drilling rig 10 and in the well, in particular tubulars, but optionally also other items such as drill string tools, bottom hole assembly, etc. The database 61 may also comprise equipment such as containers and the inventory of the containers. The database 61 comprises information of the plurality of equipment, the information comprising an identification and a location of each of the plurality of equipment on the drilling rig or in the well. For tubulars, the database 61 may comprise information about the length and/or volume of each tubular. The database 61 further comprises information on the location of the tubulars on the offshore drilling rig 10 or in the well.

Tubulars have a nominal length and volume in production; however, real tubulars may differ from the nominal values. When new tubulars arrive on the offshore drilling rig 10, they are placed in a bay 31 on the pipe deck 30. At this stage, for the bay 31, the database 61 may comprise the number of tubulars in the bay, the type of tubulars, and their nominal length and volume.

In a next step, each (or a selection of) tubulars can be measured to determine the actual dimensions of the tubulars. The system 60 may comprise at least one measurement device 67 which is adapted to measure the physical dimensions of the tubulars, such as a laser tool, a measurement band, or any other suitable measurement device. The actual dimensions of the tubulars are then entered into the database 61 for each of the measured tubulars. The measurement device 67 may transmit an update message to the database 61 comprising the identification of the equipment and the measurement to the database 61. Dimension information for the tubulars comprises at least one of length, outer diameter, inner diameter, displacement and weight. Each tubular may be given a unique identification (ID) in the database 61.

If the equipment comes with pre-defined ID markers, such as RFID chips or other markers, the ID of the equipment may be read by a scanner 66 which is adapted to identify the identification of the equipment, such as an RFID reader or an optical reading device, and input into the database 61. The actual dimensions of a tubular are entered into the database 61 together with the ID of the tubular. The actual dimensions can be entered into the system manually by an operator performing the measurements, or directly into the system by measurement devices 67 which are in communication with the database 61.

If the tubulars do not come with pre-defined ID's, the tubulars may be fitted with an ID-marker, such as RFID chips or other markers, then read by a scanner 66, such as an RFID reader or an optical reading device, and input into the database 61. The actual dimensions of a tubular are entered into the database 61 together with the ID of the tubular. The actual dimensions can be entered into the system manually by an operator performing the measurements, or directly into the system by measurement devices 67 in communication with the database 61.

If the tubulars do not come with pre-defined ID's, the actual dimensions of a tubular may alternatively be entered into the database without an ID of the tubular. The actual dimensions may be entered into the system manually by an operator performing the measurements or directly into the system by measurement devices 67 in communication with the database 61. The system may then generate and output an ID for the relevant tubular to the operator. The ID may be based on a hash of the actual dimensions of the tubular, a random generated number, an item counter or any other useful ID generation scheme. The operator can mark the tubular with the ID, for example, by writing the ID as text on the tubular.

The database now comprises information about the actual dimensions of each of the tubulars assigned to a unique ID for each tubular.

Once a tubular in a bay 31 is handled by handling equipment, such as the pipe deck pipe handler 40 and/or the tubular feeding machine 50, and transported onto the drill floor 20, the database 61 is updated with the new location of the tubular based on the ID of the tubular. A scanner 66 may read the ID of the tubular when the tubular is handled by handling equipment, such as the pipe deck pipe handler 40, the tubular feeding machine 50, the vertical pipe handlers, etc. The tubulars are handled by the relevant drill floor machinery on the drill floor 20. Multiple sections of drill string, typically three, are mounted together into a stand and stored in a slot of one of the fingerboards 21. The ID of each of the sections, the order of them in the stand, an identification of the slot of the fingerboard, as well a position within that slot may be entered into the database 61 by the tracker module 62. Other tubulars, such as casings, may be stored in different slots of the fingerboard 21. The ID of the tubular, an identification of the slot of the fingerboard, as well as the position within that slot are entered into the database 61 by the tracker module 62 having a processor 68 adapted to, for each of the plurality of equipment, track the location of the equipment and, once handled by a handling equipment, transmit an update message to the database comprising the identification of the equipment and the location of the equipment. As a tubular is moved by a machine, the tracker module 62 tracks the tubular and continuously updates the database 61 of its actual location. Possible locations for a tubular comprises, for example, slots in fingerboards 21, the drill string, the well, the mouse hole, and other positions on the drill floor 20.

The database 61 may have a pre-determined set of positions that make up possible locations for any one item. Any tubular which enters the rig, for example, from the time it is loaded onto the pipe deck 30, can thereby be tracked continuously. Some such items may be arranged in a drill string and move into and out of the well several times (for example, during tripping), whereby some items (such as casing) may be provided to the rig and permanently positioned in the well. Such a permanent position in the well may make up one storage position within the database 61.

In one embodiment, the system 60 can, for example, further comprise a condition tracker module 65 which is connected to the database 61. The condition tracker module 65 has a processor 68 which is adapted to track the working conditions of the equipment continuously, and to transmit an update message to the database 61 comprising the identification of the equipment and the working conditions for that equipment. The condition tracker module 65 may track the total rotation hours, total circulation hours, and total number of make/brake operations for tubulars. The condition tracker module 65 may also obtain input from a manual observation and control of the tubulars. The condition tracker module 65 may, based on the position of a tubular in the well, the total rotation hours, total circulation hours, or the total make/brake operations for a tubular, indicate to the system that a new measurement or test should be taken of the tubular. When new measurements have been performed on a tubular, the database can be updated with the measured actual dimensions of the tubular together with the unique ID for the tubular. The difference, or lack of difference, in the measured actual dimensions from the previous dimensions in the database 61, may be uploaded to the condition tracker module 65. The condition tracker module 65 may use the difference, or lack of difference, between the dimension to create or update a model to predict wear of tubulars. The condition tracker module 65 may, for example, create this model using artificial intelligence training methods.

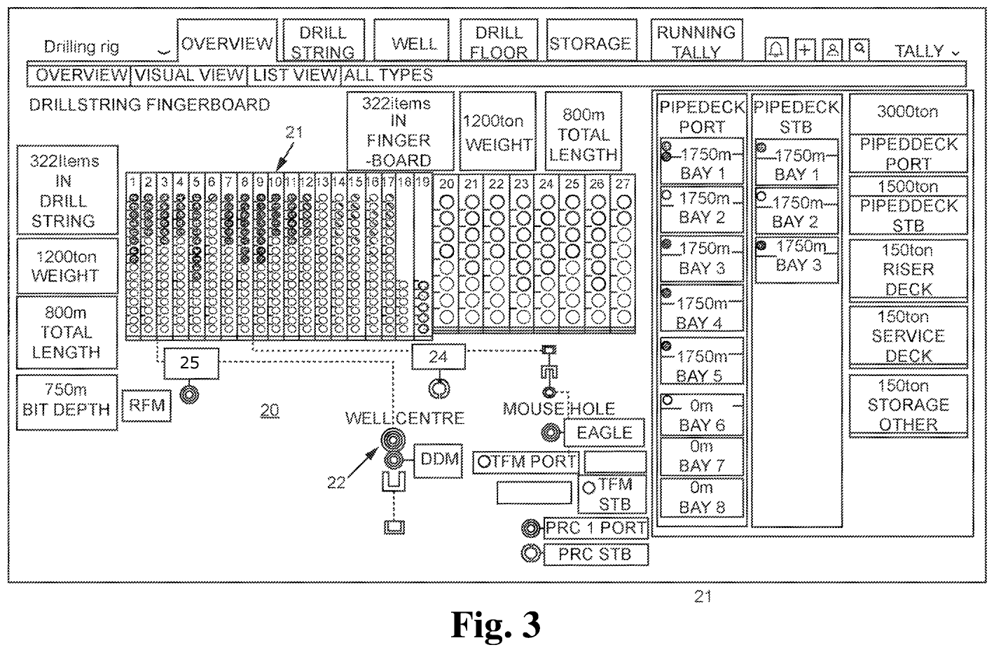

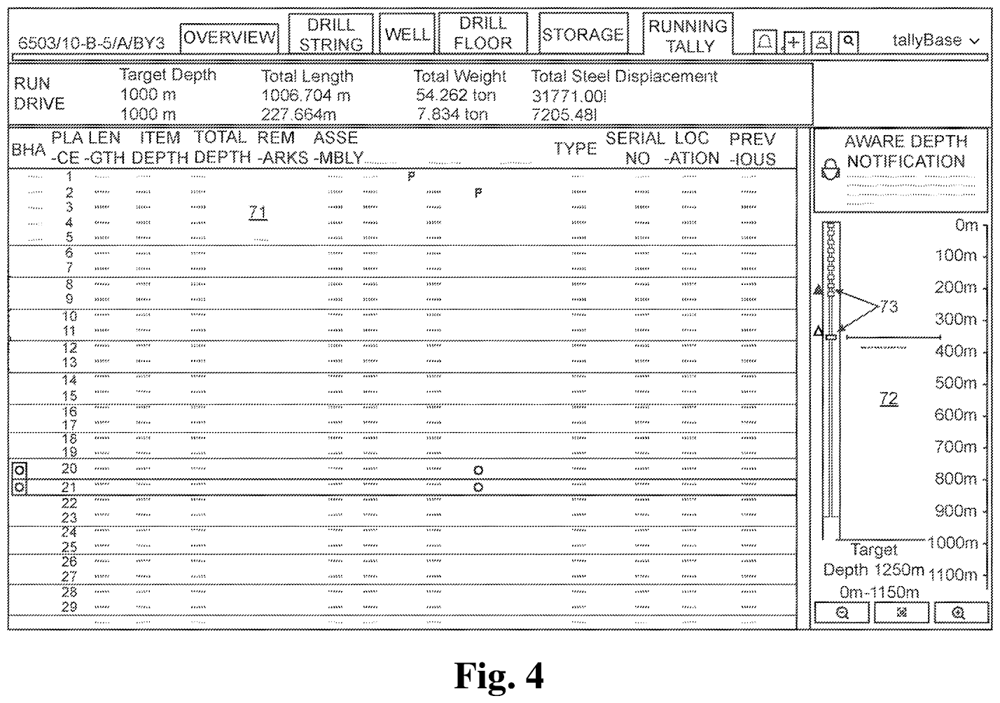

The graphical interface module 64 having a processor 68 is connected to the database 61 and a display device, such as a monitor, and displays the inventory to a user of the system 60. The user may be an operator on the offshore drilling rig or personnel at an onshore facility. The graphical interface module 64 may display the inventory in a plurality of dashboards. The visual layout may be a list of all items of a visual view of the items. A dashboard as shown in FIG. 3 comprising an illustration of a top view of a drill floor 20 of the drilling rig with a fingerboard 21, the well center 22, two vertical pipe handlers 24, 25, a mouse hole and other positions/equipment of the offshore drilling rig 10. In the slots of the fingerboard 21, various dots of different color and sizes represents the position and type of different tubulars. The overview may also show the weight of the drill string, the bit depth, the total length of the drill string, the available length of tubulars in the bays 31 of the pipe deck 30, etc. In other views, such as an overview of the tubulars in the well, or a running tally as illustrated in FIG. 4, the tubulars are presented in a list view 71. The list view 71 may be sorted based on depth, type of tubular, drill string length etc. In one embodiment, the visual layout can, for example, comprise a side view of the well 72. In one alternative embodiment, the list and/or side view can, for example, further comprise depth awareness notifications 73 which flag particular depths for elements in the well which the operator should be aware of.

The management of equipment on the drilling rig and in the well may be performed in the context of working processes, such as drilling, tripping in or tripping out. The processes can be planned in well plans that list each step of the processes, including a sequence of tubulars that are going into the well. The planner module 63 has a processor 68 and is adapted to receive well information and receive, from the database 61, the information of the plurality of equipment; and based on the well information and the information of the plurality of equipment, create a first drilling sequence of tubulars to go into the well. That is, the planner module 63 of the system 60 is connected to the database 61 so that the well plan can be based on the inventory list from the database 61. As the database 61 has knowledge of the actual dimensions of the tubulars, as well as the condition for the tubulars, the planner module 63 can verify during planning that a planned drill string is optimal according to relevant restrictions in the well, e.g., such that that the equipment does not exceed it's planned life or that the equipment is suitable for where it will be positioned in the well based on the well information. The planner module 63 provides a digital plan that may be distributed to other stakeholders and service, both onshore and offshore.

In some instances, a planned drilling sequence may be under execution when measured data indicate that a change to the planned drilling sequence is necessary. During drilling it may, for example, be established that a section of the well needs to be cased earlier than originally planned. The fingerboards may in this event have a plurality of tubulars stored for use in the well according to the original plan, when the drilling sequence is stopped and a tripping out procedure is started.

If the planner module 63 receives updated well information during drilling according the first drilling sequence, it creates a second drilling sequence of tubulars to go into the well based on the updated well information and the information of the plurality of equipment, and, based on the second drilling sequence, plans a storage position suitable for the second drilling sequence for each of the equipment going out of the well.

The planner module 63 may receive the new well plan from shore with updated geological info, for example, via a data link as illustrated below.

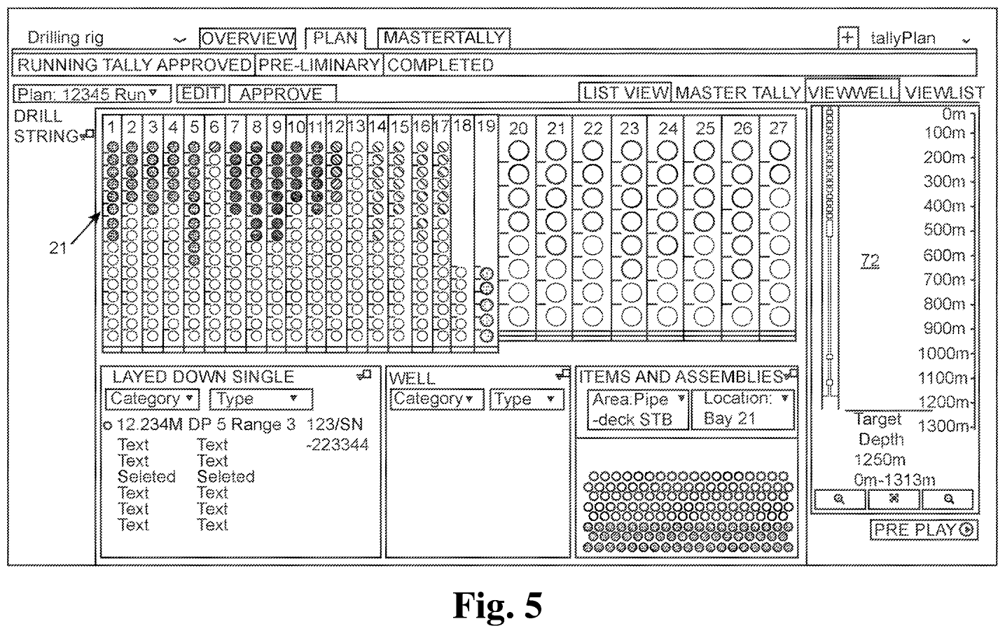

The graphical interface module 64 is in one embodiment connected to the planner module 63. In one embodiment, as illustrated in FIG. 5, the planner module 63 can, for example, comprise a visual drag and drop tool. The drag and drop tool shows the available tubulars in the database 61. A visual representation of the fingerboard 21 shows available tubulars represented by the various dots of different color and sizes that represents the type of the tubulars. The colors may also represent a condition of the tubular. There may also be a visual representation of tubulars available at the pipe deck. The drag and drop tool is also provided with a visual representation of the well as seen from the side, a side view of the well 72. When planning the well, plan tubulars may be selected from the fingerboards and/or the pipe deck, dragged, and dropped into the well view. As described above, one alternative embodiment the well view comprises notifications flagging particular depths for elements in the well the operator should be aware of. The user then easily see that a certain selection of tubular should or should not be made. The notification may have a color that matches the color of a tubular in the fingerboard suitable for that position in the well.

The database may continuously provide the exact position of each tubular based on the knowledge of the exact length of each tubular and the position in the well. The system may thus at any time provide a driller with the exact drilling depth, or depth of certain parts of the drill string, such as the bottom hole assembly. On one embodiment, a method for determining a position of a part of a tool string in relation to a well using the drilling plant management system is thus performed comprising determining, based on the location of each equipment in the database, all equipment located in the well, determining, based on the information of each equipment in the database, the length, i.e., actual length, of each equipment located in the well. The method further comprises determining the total, i.e., actual, length a well string by summing up the length of each equipment located in the well and determining the position of the part of the tool string in relation to the well based on the total length of the well string. The length of each equipment in the database may be a measured length. The length of each equipment in the database may be calculated based the conditions of the equipment in the database, e.g., machine learning may be utilized to learn from the information in the database and predict length changes etc. of the equipment in use.

In one embodiment, the method can, for example, be employed to determine whether the position of a part of a tool string is in a blow out preventer, where the part is, for example, a tool joint or a hard component.

The database may continuously provide the exact volume of the tubulars, e.g., volume of metal, in the drill string. The driller has knowledge of the amount of drilling fluid pumped into the well and the amount of drilling fluid pumped out of the wellbore. This, together with the knowledge of the exact volume of the tubulars in the drill string and knowledge, or at least an estimate of, the volume of the riser, cased well, and open hole section of the well, allows the driller to make calculations of influx/outflux in the subterranean wellbore with increased precision. In one embodiment, a method of estimating a fluid volume in a well using the drilling plant management system is thus performed, the method comprising providing a plurality of tubulars to a drilling rig, logging physical dimensions of each tubular in the database, the physical dimensions including a volume of material for the tubular, logging with the tracking module tubulars that are positioned the well, determining material volume of the tubulars positioned in the well, and calculating the fluid volume based on well dimensions and the combined material volume of the tubulars in the well. The physical dimensions may include an inner diameter and an outer diameter of a pipe section. The influx or loss of drilling fluids may also be estimated by calculating well volume. The estimation of the influx or loss of drilling fluids may take into account volume change from a drill string moving into or out of the well.

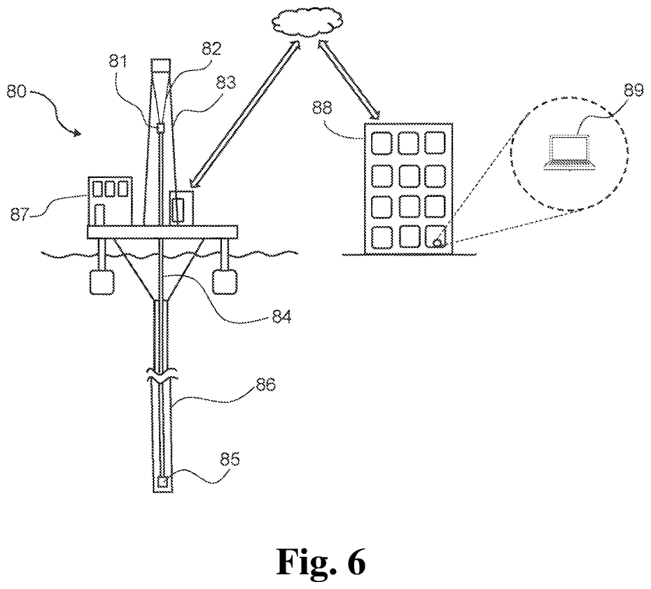

FIG. 6 illustrates schematically a drilling rig 80 comprising a top drive 81, and a hoisting system 82 operating the top drive 81 in a rig structure 83 to suspend a drill string 84 having a drill bit 85 into a subterranean wellbore 86. Several components of the handling system 60, such as the database 61, the tracker module 62, the planner module 63, the graphical interface module 64, and the condition tracker module 65, may be arranged in a control center 87 on the rig 80.

In an alternative embodiment, parts of the system 60, the such as the database 61, the tracker module 62, the planner module 63, the graphical interface module 64, and the condition tracker module 65, may be located on a shore-based location, which is here illustrated as office 88. The office comprises a computer 89. The computer 89 may be in bi-directional communication with the handling system via a data link, which is illustrated in FIG. 6 with the double arrows and an intermediate “cloud” storage, however, the data link may be a direct link between the drilling rig 80 and the office 88. The data link may be a substantially real-time data link, or it may be set up to provide repeated, intermittent communication of the relevant data.

The handling system 60 may optionally be arranged on the drilling rig 80, but the output of the graphical interface module 64 is mirrored at the shore location.

In an embodiment, the shore-based computer 89 can, for example, comprise a well plan for the well, which is provided to the control center 87 via the data link.

In one embodiment, the method may, for example, include operating the drilling rig 80 according to a well plan and a planned sequence of building a drill string 84 from a plurality of equipment items and bringing the drill string 84 into a wellbore 86, each equipment item prior to being arranged in the drill string 84 being positioned in a defined position on the drilling rig 80 stored in the database 61; identifying a change in the well plan or the planned sequence and a need to prematurely retrieve the drill string 84 from the wellbore 86; operating the planner module 63 to, in that order, (i) plan a subsequent construction sequence of the drill string 84 from the plurality of equipment items in view of physical properties of each equipment item received from the database 61, and (ii) allocate a defined position on the rig to each equipment element to be retrieved from the wellbore 86; and operating the drilling rig to: (i) retrieve the drill string 84 from the wellbore 86, break up the drill string 84, and place each equipment item broken out of the drill string 84 in the allocated position for that equipment item, and (ii) retrieve a plurality of equipment items from their storage positions, build a drill string 84 according to the planned sequence, and introduce the drill string 84 into the wellbore 86.

The method according to this embodiment advantageously improves safety and operational efficiency during, for example, an unexpected need for well casing. This situation may arise, for example, if the downhole formation is shown to have different properties than predicted, and casing for well support is required earlier than expected. The subsequent building of the drill string may in this case be planned based on the physical properties of the known equipment elements to provide accurate knowledge of the drill string 84 to be constructed during the next run. The condition tracker module 65 may also be employed to determine which items should be re-used in the next run. If, for example, a tool joint has reached its maximum number of make/break operations before an inspection or replacement is required, this stand may be removed and not included in the planning for the next run.

The allocation of a position for each item retrieved from the well may take into account an order which the same items are to be retrieved from the fingerboard 21 during the next construction according to the planned sequence, and place the retrieved items in the fingerboard 21 so that they can be retrieved successively without the need to move items from one slot to another to obtain access to another, required item.

In any of the embodiments herein, the location of an item may be a unique location out of a finite number of storage locations stored in the database 61.

The present invention is not limited to embodiments described herein; reference should be had to the appended claims.

### LIST OF REFERENCE NUMERALS

10 Offshore drilling rig
20 Drill floor
21 Fingerboards
22 Well center
23 Hoisting and drilling system
24 Vertical pipe handler
25 Vertical pipe handler
30 Pipe deck
31 Bays
40 Pipe deck pipe handler
50 Tubular feeding machine
51 Supply ship
60 Drilling plant management system
61 Database
62 Tracker module
63 Planner module
64 Graphical interface module
65 Condition tracker module
66 Scanner
67 Measurement device
68 Processor (of Controller)
71 List view
72 Side view of the well
73 Depth awareness notifications
80 Drilling rig
81 Top drive
82 Hoisting system
83 Rig structure
84 Drill string
85 Drill bit
86 Wellbore
87 Control center
88 Office
89 Computer

What is claimed is:

1-23. (canceled)

24: A drilling plant management system comprising:
a database comprising information of equipment items on a drilling rig and in a well, the information comprising an identification and a location of each of the equipment items on the drilling rig or in the well;
a controller comprising processor, the controller being configured to receive update messages comprising the identification of an equipment item and information related to the equipment item, and to update the database with the information in the update message; and
a tracker module which is configured, via the processor, to track a location of each of the equipment items and, once handled by a handling equipment, to transmit an update message to the database comprising the identification of the equipment item and the location of the equipment item.

25: The system as recited in claim 24, further comprising:
a planner module which is configured, via the processor, to receive well information and to receive, from the database, the information of the equipment items, and based on the well information and the information of the equipment items, to create a first drilling sequence of tubulars to make up a drill string to go into the well.

26: The system as recited in claim 25, wherein the planner module is further configured to,
during a drilling according the first drilling sequence of tubulars, receive updated well information,
to create a second drilling sequence of tubulars to go into the well based on the updated well information and the information of the equipment items, and
based on the second drilling sequence of tubulars, to plan a storage position suitable for the second drilling sequence of tubulars for each of the equipment items going out of the well.

27: The system as recited in claim 25, further comprising:
a condition tracker module which is configured, via the processor, to track working conditions of the equipment item and to transmit an update message to the database comprising the identification of the equipment item and working conditions for the equipment item.

28: The system as recited in claim 27, wherein the equipment item is a tubular and the working conditions includes at least one of a total rotation hours, a total circulation hours and a total number of make/brake operations carried out on the tubular.

29: The system as recited in any of claim 25, wherein,
the information of the equipment items includes working conditions of the equipment items, and
the planner module is further configured to create at least one of a first drilling sequence and a second drilling sequence while taking into consideration a working condition of each of the equipment items so that that the equipment item does not exceed a planned operational life or that the equipment item is suitable for its planned position in the well based on the well information.

30: The system as recited in claim 24, further comprising:
a graphical interface module which is configured, via the processor, to display on a display device the information in the database of the equipment items on the drilling rig and in the well in a visual layout comprising a top view of a drill floor of the drilling rig.

31: The system as recited in claim 24, further comprising:
a graphical interface module which is configured, via the processor, to display on a display device the information in the database of the equipment items on the drilling rig and in the well in a visual layout comprising a side view of the well.

32: The system as recited in claim 31, wherein the side view further comprises a depth awareness notification.

33: The system as recited in claim 24, wherein the database further comprises a pre-determined set of positions which include a possible location for each of the equipment items on the drilling rig and in the well.

34: The system as recited in claim 24, wherein,
the equipment item is a tubular, and
the database further comprises information on at least one of a length and a volume of the tubular.

35: The system as recited in claim 24, further comprising:
at least one measurement device which is configured to measure a physical dimension of the equipment item and to transmit an update message to the database comprising the identification of the equipment item and the physical dimension measured.

36: The system as recited in claim 24, further comprising:
a least one scanner which is configured to identify the identification of the equipment item.

37: A method of estimating a fluid volume in a well using the drilling plant management system as recited in claim 27, the method comprising:
providing tubulars to a drilling rig;
logging physical dimensions of each of the tubulars in the database, the physical dimensions including a volume of material for each of the tubulars;
logging tubulars that are positioned in the well via the condition tracker module;
determining a material volume of the tubulars positioned in the well; and
calculating the fluid volume based on well dimensions and the combined material volume of the tubulars in the well.

38: The method as recited in claim 37, wherein the physical dimensions include an inner diameter and an outer diameter of each of the tubulars.

39: The method as recited in claim 37, wherein the method further comprises:
estimating an influx of fluids from a formation or a loss of drilling fluids to the formation.

40: The method as recited in claim 39, further comprising:
calculating a volume change of material volume from a drill string moving into or out of the well as a function of a measured fluid flow rate into the well and a measured fluid flow rate out of the well.

41: A method for determining a position of a part of a tool string in relation to a well using the drilling plant management system as recited in claim 24, the method comprising:
determining, based on a location of each of the equipment items in the database, all of the equipment items located in the well;
determining, based on the information of each of the equipment items in the database, a length of each equipment item located in the well;
determining a total length of a well string by adding together each length of each of the equipment items located in the well; and
determining a position of a part of the tool string in relation to the well based on the total length of the well string determined.

42: The method as recited in claim 41, wherein the length of each of the equipment items in the database is a measured length.

43: The method as recited in claim 41, wherein the length of each of the equipment items in the database is calculated based on a stored condition for the equipment item in the database.

44: The method as recited in any of claim 41, wherein the position is a position in a blow out preventer and the part is a tool joint or a hard component.

45: A method of operating a drilling rig, the method comprising:
operating the drilling rig as recited in a well plan and a planned sequence of building a drill string from equipment items and bringing the drill string into a well, each of the equipment items, prior to being arranged in the drill string, being positioned in a defined position on the drilling rig stored in a database;
identifying a change in the well plan or the planned sequence and a need to prematurely retrieve the drill string from the well;
operating a planner module so as,
to firstly plan a subsequent construction sequence of the drill string from the equipment items in view of physical properties of each of the equipment items received from the database, and
to secondly allocate a defined position on the drilling rig to each equipment element to be retrieved from the well; and
operating the drilling rig,
to retrieve the drill string from the well, break up the drill string, and place each of the equipment items broken out of the drill string in the allocated position for an individual equipment item, and
to retrieve equipment items from their storage positions, build the drill string as recited in the planned sequence, and introduce the drill string into the well.

46: The method as recited in claim 45, further comprising:
operating a condition tracker module so as to determine whether one of the equipment items is unsuitable for use in the planned sequence, and
blocking the one of the equipment items from being used in the planned sequence.
